(19) United States
(12) Patent Application Publication
(10) Pub. No.: US 2010/0101650 A1
(43) Pub. Date: Apr. 29, 2010

(54) COMPOUND, PHOTOELECTRIC CONVERSION DEVICE AND PHOTOELECTROCHEMICAL BATTERY

(75) Inventors: Toshiya Takahashi, Osaka (JP); Kunihito Miyake, Ibaraki (JP); Akio Tanaka, Hyogo (JP); Tetsuo Kawata, Osaka (JP)

Correspondence Address: SUGHRUE MION, PLLC, 2100 PENNSYLVANIA AVENUE, N.W., SUITE 800, WASHINGTON, DC, 20037, US

(73) Assignee: SUMITOMO CHEMICAL COMPANY ,LIMITED, Chuo-ku ,Tokyo (JP)

(21) Appl. No.: 12/519,467

(22) PCT Filed: Dec. 14, 2007
(86) PCT No.: PCT/JP2007/074596

§ 371 Date: Dec. 8, 2009

(30) Foreign Application Priority Data
Dec. 18, 2006 (JP) 2006-339615

(51) Int. Cl. H01L 31/00; C07F 15/00

(52) U.S. Cl. 136/261; 546/12

(57) ABSTRACT

The present invention provides a complex compound (I) obtained by coordinating a ligand represented by the formula (II) below and a bidentate ligand to a metal atom,

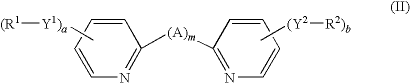

wherein, in the formula, Y¹ and Y² each independently represent a group containing an unsaturated aliphatic hydrocarbon and an aromatic ring; R¹ and R² each independently represent a salt of an acidic group or an acidic group; A represents a group containing a nitrogen atom, an oxygen atom, a carbon atom, a silicon atom, a sulfur atom or a selenium atom; and m, a, and b each independently represent an integer of 0 to 2, while satisfying a+b≧1.

### TECHNICAL FIELD

The present invention relates to a compound, a photosensitizing coloring matter containing the compound, a photoelectric conversion device containing the coloring matter, and photoelectrochemical batteries such as a solar battery containing the photoelectric conversion device, and the like.

### BACKGROUND ART

Recently, for prevention of global warming-up, reduction of CO₂ discharged into atmosphere is required. As an influential means for reduction of CO₂, for example, there is a proposal for switching into a solar system using a photoelectrochemical battery such as a pn junction type silicon-based solar battery or the like on the roof of a house. However, a single crystalline, polycrystalline and amorphous silicon used in the above-described silicon-based photoelectrochemical battery have a problem that they are expensive because of necessity of high temperature and high vacuum conditions in the production process thereof.

In contrast, JPH07-500630-A suggests a photoelectrochemical battery containing a photoelectric conversion device having an easily-producible photosensitizing coloring matter adsorbed on the surface of a semiconductor fine particle made of titanium oxide and the like, and specifically, reports that a compound of the formula (1) shows excellent photoelectric conversion efficiency.

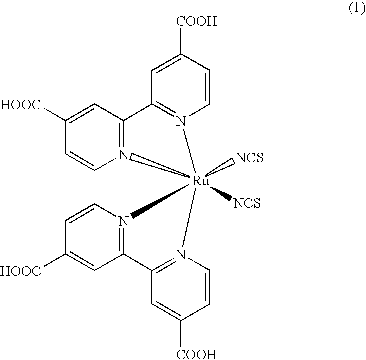

The present inventors have investigated a photoelectrochemical battery containing a photosensitizing coloring matter (1), where it becomes clarified that the photoelectric conversion efficiency is not sufficient from the visible light region to long wavelength region, particularly, in a long wavelength region of 700 nm or more.

The present invention has an object of providing a compound which gives a photoelectric conversion device showing high photoelectric conversion efficiency in wide range from the visible light region to long wavelength region, a coloring matter for photoelectric conversion device containing the compound, a photoelectric conversion device containing the coloring matter, and a photoelectrochemical battery containing the device.

### DISCLOSURE OF THE INVENTION

The present invention includes a complex compound (I) which is obtained by coordinating a ligand represented by the formula (II) and a bidentate ligand to a metal atom; a photosensitizing coloring matter containing said complex compound (I); a photoelectric conversion device containing the coloring matter; and a photoelectrochemical battery containing the device.

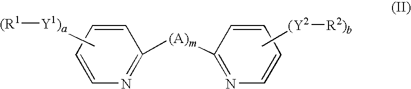

In the formula (II), Y¹ and Y² each independently contain an unsaturated aliphatic hydrocarbon group and an aromatic ring; R¹ and R² each independently represent a salt of an acidic group or an acidic group; A represents a group containing a nitrogen atom, an oxygen atom, a carbon atom, a silicon atom, a sulfur atom or a selenium atom, and m, a, and b each independently represent an integer of 0 to 2, while satisfying a+b≧1.

The bidentate ligand includes bipyridine derivatives, phenanthroline derivatives, ligands (II), (III) and (IV) shown below, and the like, and particularly, the ligands (II), (III) and (IV) are preferable.

Preferable are a complex compound (I′) which is obtained by coordinating two molecules of a ligand represented by the formula (II) to a metal atom; a photosensitizing coloring matter containing said complex compound (I); a photoelectric conversion device containing said coloring matter; and a photoelectrochemical battery containing said device.

Alternatively, preferable are a complex compound (I″) which is obtained by coordinating a ligand represented by the formula (II) and a ligand represented by the formula (III) to a metal atom; a photosensitizing coloring matter containing said complex compound (I″); a photoelectric conversion device containing said coloring matter; and a photoelectrochemical battery containing said device.

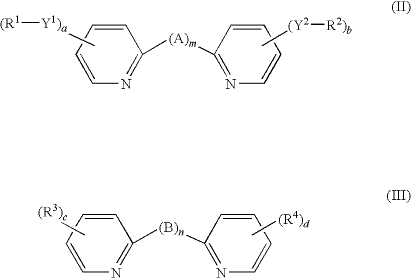

In the formulae, Y¹ and Y² each independently contain an unsaturated aliphatic hydrocarbon group and an aromatic ring, and R¹, R², R³ and R⁴ each independently represent a salt of an acidic group or an acidic group. A and B each independently represent a group containing a nitrogen atom, an oxygen atom, a carbon atom, a silicon atom, a sulfur atom or a selenium atom, and m, n, a, b, c and d each independently represent an integer of 0 to 2, while satisfying a+b≧1, c+d≧1.

Alternatively, provided are a complex compound (I′″) which is obtained by coordinating a ligand represented by the formula (II) and a ligand represented by the formula (IV) to a metal atom; a photosensitizing coloring matter containing said complex compound (I′″); a photoelectric conversion device containing said coloring matter; and a photoelectrochemical battery containing said device.

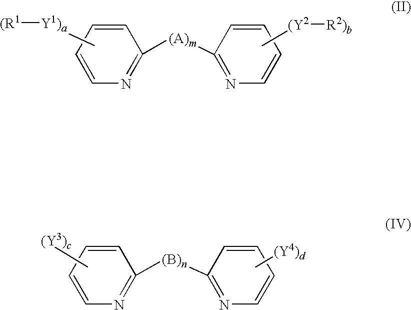

In the formulae, R¹ and R² each independently represent a salt of an acidic group or an acidic group. Y¹, Y², Y³ and Y⁴ each independently represent a group containing an unsaturated aliphatic hydrocarbon group and an aromatic ring, A and B each independently represent a group containing a nitrogen atom, an oxygen atom, a carbon atom, a silicon atom, a sulfur atom or a selenium atom, and m, n, a, b, c and d each independently represent an integer of 0 to 2, while satisfying a+b≧1, c+d≧1.

### BRIEF EXPLANATION OF DRAWING

FIG. 1 is a sectional schematic view of a photoelectrochemical battery of the present invention.

### DESCRIPTION OF MARKS

1: substrate
2: electroconductive layer
3: semiconductor particle layer
4: photosensitizing coloring matter
5: electrolytic solution
6: electroconductive layer
7: substrate
8: electroconductive substrate
9: counter electrode (electroconductive substrate)
10: sealant

### BEST MODE FOR CARRYING OUT THE INVENTION

The present invention will be illustrated in detail below.

The present invention includes a complex compound (I) which is obtained by coordinating a ligand represented by the above-described formula (II) and a bidentate ligand to a metal atom.

The metal atoms include Ti and Zr in the group IV metal atoms, Fe, Ru and Os in the group VIII metal atoms, Co, Rh and Ir in the group IX metal atoms, Ni, Pd and Pt in the group X metal atoms, Cu in the group XI metal atoms, Zn in the group XII metal atoms, and the like, and preferable are group VIII metal atoms, and more preferable is Ru.

In the formulae (II), (III) and (IV), R¹, R², R³ and R⁴ each independently represent a salt of an acidic group or an acidic group. Examples of the acidic group include a carboxyl group, sulfonic group (—SO₃H), squaric group, phosphoric group (—PO₃H₂), boric group (—B(OH)₂) and the like. Particularly, a carboxyl group is suitable.

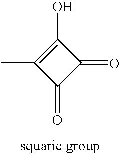

The salt of an acidic group includes salts with organic bases, and specifically, includes a tetraalkylammonium salt, imidazolinium salt, pyridinium salt and the like.

a, b, c and d each independently represent an integer of 0 to 2, preferably satisfying a+b≧1, c+d≧1, more preferably a=b=1,

Y¹, Y², Y³ and Y⁴ each independently represent a group containing an unsaturated aliphatic hydrocarbon group (olefinic hydrocarbon group or acetylenic hydrocarbon group) and an aromatic ring, and preferable is a group capable of conjugating with a pyridine ring in the formula (II) or (IV).

From the standpoint of easiness of production, it is preferable that, independently, Y¹ and Y² are identical, and Y³ and Y⁴ are identical.

Examples of Y¹, Y², Y³ and Y⁴ include groups represented by the formula (V) or the formula (V′), and preferable are groups represented by the formula (V).

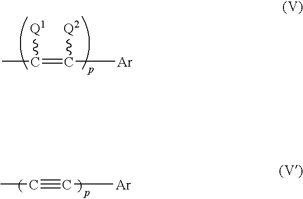

In the formulae (V) and (V′), Ar represents an optionally substituted aryl group, Q¹ and Q² each independently represent a hydrogen atom, an alkyl group having 1 to 20 carbon atoms, an aryl group having 6 to 20 carbon atoms, or a cyano group, and p represents an integer of 1 to 3.

As Ar, the following examples are mentioned. Marks * and ** in the following examples represent bonding positions to other groups, but the bonding positions are not limited to them. As Ar, groups represented by the formula (A-1) or the formula (A-4) are preferable.

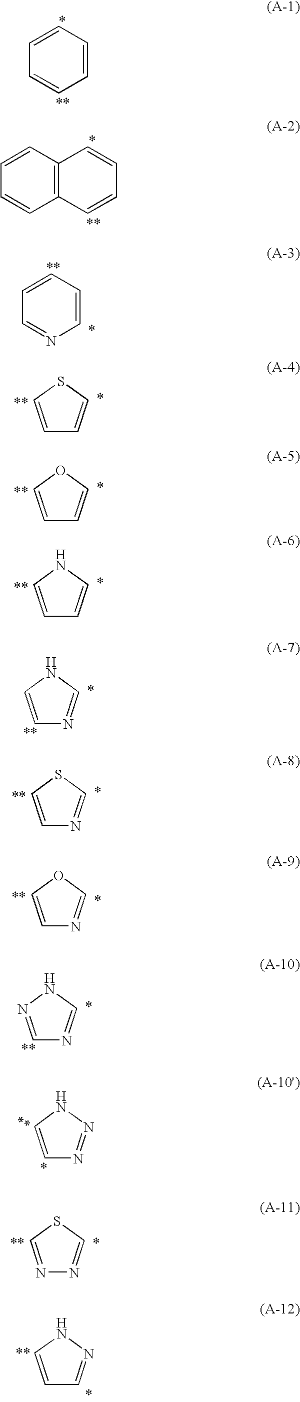

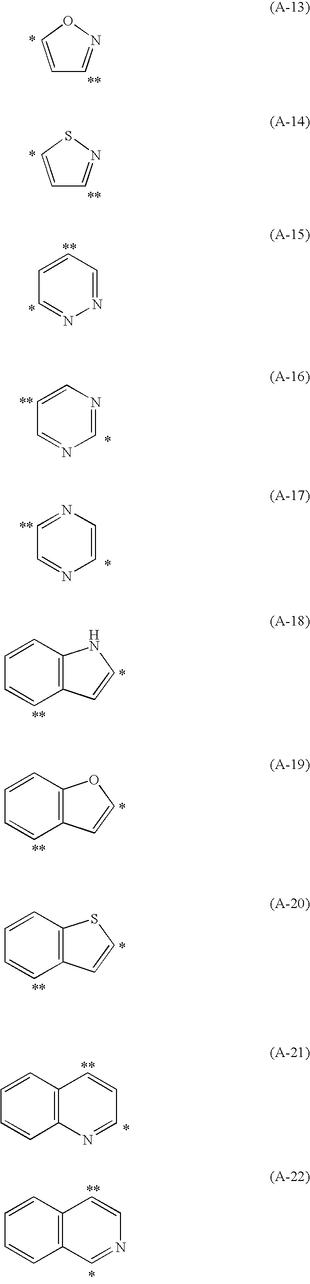

Specific examples of Q¹ and Q² include a hydrogen atom, an alkyl group having 1 to 20 carbon atoms, an aryl group having 6 to 20 carbon atoms or a cyano group. Examples of the alkyl group having 1 to 20 carbon atoms include linear alkyl groups such as a methyl group, an ethyl group, a n-propyl group, a n-butyl group, a n-hexyl group, a n-pentyl group, a n-octyl group and a n-nonyl group; branched alkyl groups such as an i-propyl group, a t-butyl group and a 2-ethyl-hexyl group; alicyclic alkyl groups such as a cyclopropyl group and a cyclohexyl group. Examples of the aryl group having 6 to 20 carbon atoms include a phenyl group, a naphthyl group and the like.

Specific examples of the substituent for Ar include a hydrogen atom, a hydroxyl group, alkyl groups having 1 to 20 carbon atoms, alkoxy groups having 1 to 20 carbon atoms, aryloxy groups having 6 to 20 carbon atoms, dialkylamino groups having 2 to 20 carbon atoms, and diarylamino groups having 12 to 20 carbon atoms. Examples of the alkyl groups includes linear alkyl groups such as a methyl group, an ethyl group, a n-propyl group, a n-butyl group, a n-hexyl group, a n-pentyl group, a n-octyl group and a n-nonyl group; branched alkyl groups such as an i-propyl group, a t-butyl group and a 2-ethyl-hexyl group; alicyclic alkyl groups such as a cyclopropyl group and a cyclohexyl group. Examples of the aryl group include a phenyl group, a naphthyl group and the like.

In the formula (V) or the formula (V′), p represents an integer of 1 to 3, preferably, p=1. A structural isomer of E configuration or Z configuration may be used, and a mixture of E and Z may also be used.

In the group represented by the formula (V) or (V′), one end of unsaturated aliphatic hydrocarbons is connected to a pyridine ring, and another end is connected to the bonding position ** of Ar. The bonding position * of Ar is connected to R¹ or R², or a substituent.

Both of Y¹ and Y² are preferably a group represented by the formula (V), and especially, preferable are groups in which Ar is thiophene and p is 1.

In the formulae (II), (III) and (IV), A and B each independently represent a group containing a nitrogen atom, an oxygen atom, a carbon atom, a silicon atom, a sulfur atom or a selenium atom.

m and n each independently represent an integer of 0 to 2, and preferably, m=n=0.

Specific examples of -(A)m- and -(B)n- include —S—, —O—, —SO₂—, —P(R⁵)—, —N(R⁵)—, —C(R⁵)(R⁶)—, —Si(R⁵)(R⁶)—, —Se— and the like, preferably —S—. R⁵ and R⁶ each independently represent a hydrogen atom, or an alkyl group having 1 to 20 carbon atoms or an aryl group having 6 to 20 carbon atoms. Examples of the alkyl group having 1 to 20 carbon atoms include linear alkyl groups such as a methyl group, an ethyl group, a n-propyl group, a n-butyl group, a n-hexyl group, a n-pentyl group, a n-octyl group and a n-nonyl group; branched alkyl groups such as an i-propyl group, a t-butyl group and 2-ethyl-hexyl group; alicyclic alkyl groups such as a cyclopropyl group and cyclohexyl group. Examples of the aryl group having 6 to 20 carbon atoms include a phenyl group, a naphthyl group and the like.

In a method for producing a ligand (II), for example, a 2-halogen-substituted pyridine derivative having Y¹ and Y² can be reacted together with a suitable phosphine ligand in the presence of a Ni reagent or Pd catalyst, thereby, causing a coupling reaction at the 2-position of the pyridine derivative to synthesize an intended compound (m=0) (can be represented by the formula (2)).

When A (or B) is a sulfur atom, sodium sulfide and a 2-halogen-substituted pyridine derivative having Y¹ and Y² can be reacted in an organic solvent, to obtain an intended compound crosslinked with a sulfur atom (m=1, 2, hereinafter, referred to as S-crosslinked body in some cases) (can be represented by the formula (2)).

When A (or B) is SO or SO₂, the S-crosslinked body obtained above can be oxidized with m-chloroperbenzoic acid and the like, to obtain an intended compound.

In the method for producing a ligand (II), R¹ and R² may be subjected to a coupling reaction after introduction of a protective group such as esters (for example, methyl ester, ethyl ester, propyl ester, butyl ester), before removing the protective group.

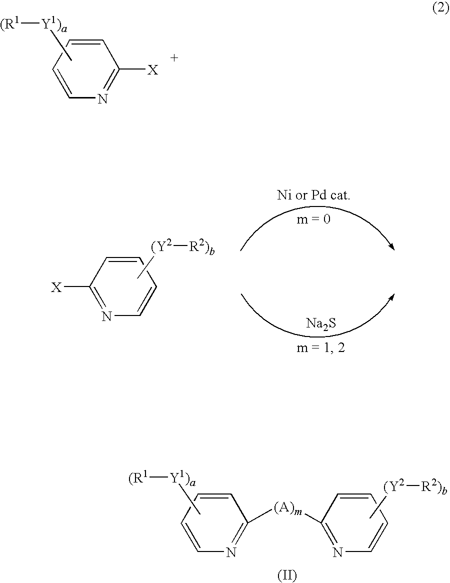

In the formulae, each of X independently represents a chlorine atom, a bromine atom or an iodine atom.

A 2-halogen-substituted pyridine derivative having Y¹ and Y² can be synthesized by a reaction of incorporating an olefin according to the Wittig reaction, Suzuki reaction and the like, and for example, it can be synthesized by a reaction shown below.

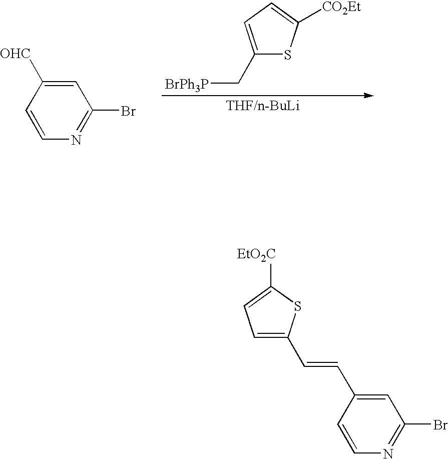

Ligands (III) and (IV) can be produced using a 2-halogen-substituted pyridine derivative, according to the production method of the ligand (II) except that -(B)n- is applied instead of -(A)m-.

Specific examples of the ligand (II) include compounds represented by the following formula and shown in Table 1.

TABLE 1

| | —(Y1—R1)ₐ | | —(Y2—R2)_{b} | | Y1═Y2 | | | | | | |
|---|---|---|---|---|---|---|---|---|---|---|---|
| Compound | Pos* | R¹ | Pos* | R² | Y1, Y2 | Ar | p | A | m | a | b |
| II-1 | 4 | —COOH | 4′ | —COOH | —(CH═CH)— | A-1 | 1 | — | 0 | 1 | 1 |
| II-2 | 4 | —COOH | 4′ | —COOH | —(CH═CH)— | A-2 | 1 | — | 0 | 1 | 1 |
| II-3 | 4 | —COOH | 4′ | —COOH | —(CH═CH)— | A-3 | 1 | — | 0 | 1 | 1 |
| II-4 | 4 | —COOH | 4′ | —COOH | —(CH═CH)— | A-4 | 1 | — | 0 | 1 | 1 |
| II-5 | 4 | —COOH | 4′ | —COOH | —(CH═CH)— | A-5 | 1 | — | 0 | 1 | 1 |
| II-6 | 4 | —COOH | 4′ | —COOH | —(CH═CH)— | A-6 | 1 | — | 0 | 1 | 1 |
| II-7 | 4 | —COOH | 4′ | —COOH | —(CH═CH)— | A-7 | 1 | — | 0 | 1 | 1 |
| II-8 | 4 | —COOH | 4′ | —COOH | —(CH═CH)— | A-8 | 1 | — | 0 | 1 | 1 |
| II-9 | 4 | —COOH | 4′ | —COOH | —(CH═CH)— | A-9 | 1 | — | 0 | 1 | 1 |
| II-10 | 4 | —COOH | 4′ | —COOH | —(CH═CH)— | A-10 | 1 | — | 0 | 1 | 1 |
| II-11 | 4 | —COOH | 4′ | —COOH | —(CH═CH)— | A-11 | 1 | — | 0 | 1 | 1 |
| II-12 | 4 | —COOH | 4′ | —COOH | —(CH═CH)— | A-12 | 1 | — | 0 | 1 | 1 |
| II-13 | 4 | —COOH | 4′ | —COOH | —(CH═CH)— | A-13 | 1 | — | 0 | 1 | 1 |
| II-14 | 4 | —COOH | 4′ | —COOH | —(CH═CH)— | A-14 | 1 | — | 0 | 1 | 1 |
| II-15 | 4 | —COOH | 4′ | —COOH | —(CH═CH)— | A-15 | 1 | — | 0 | 1 | 1 |
| II-16 | 4 | —COOH | 4′ | —COOH | —(CH═CH)— | A-16 | 1 | — | 0 | 1 | 1 |
| II-17 | 4 | —COOH | 4′ | —COOH | —(CH═CH)— | A-17 | 1 | — | 0 | 1 | 1 |
| II-18 | 4 | —COOH | 4′ | —COOH | —(CH═CH)— | A-18 | 1 | — | 0 | 1 | 1 |
| II-19 | 4 | —COOH | 4′ | —COOH | —(CH═CH)— | A-19 | 1 | — | 0 | 1 | 1 |
| II-20 | 4 | —COOH | 4′ | —COOH | —(CH═CH)— | A-20 | 1 | — | 0 | 1 | 1 |
| II-21 | 4 | —COOH | 4′ | —COOH | —(CH═CH)— | A-21 | 1 | — | 0 | 1 | 1 |
| II-22 | 4 | —COOH | 4′ | —COOH | —(CH═CH)— | A-22 | 1 | — | 0 | 1 | 1 |
| II-23 | 4 | —COOH | 4′ | —COOH | —(CH═CH)— | A-4 | 1 | —S— | 1 | 1 | 1 |
| II-24 | 4 | —COOH | 4′ | —COOH | —(CH═CH)— | A-4 | 1 | —SO2— | 1 | 1 | 1 |
| II-25 | 4 | —COOH | 4′ | —COOH | —(CH═CH)— | A-4 | 1 | —Se— | 1 | 1 | 1 |
| II-26 | 4 | —COOH | 4′ | —COOH | —(CH═CH)— | A-4 | 1 | —O— | 1 | 1 | 1 |
| II-27 | 4 | —COOH | 4′ | —COOH | —(CH═CH)— | A-4 | 1 | —NH— | 1 | 1 | 1 |
| II-28 | 4 | —COOH | 4′ | —COOH | —(CH═CH)— | A-4 | 1 | —NC2H5— | 1 | 1 | 1 |
| II-29 | 4 | —COOH | 4′ | —COOH | —(CH═CH)— | A-4 | 1 | —PCH3— | 1 | 1 | 1 |
| II-30 | 4 | —COOH | 4′ | —COOH | —(CH═CH)— | A-4 | 1 | —Si(CH3)2— | 1 | 1 | 1 |
| II-32 | 4 | —COOH | 4′ | —COOH | —(C≡C)— | A-4 | 1 | — | 0 | 1 | 1 |
| II-33 | 4 | —SO3H | 4′ | —SO3H | —(CH═CH)— | A-4 | 1 | — | 0 | 1 | 1 |
| II-34 | 4 | —SO3H | 4′ | —SO3H | —(CH═CH)— | A-4 | 1 | —S— | 1 | 1 | 1 |
| II-35 | 4 | —SO3H | 4′ | —SO3H | —(CH═CH)— | A-4 | 1 | —SO2— | 1 | 1 | 1 |
| II-36 | 4 | —SO3H | 4′ | —SO3H | —(CH═CH)— | A-4 | 1 | —Se— | 1 | 1 | 1 |
| II-37 | 4 | —SO3H | 4′ | —SO3H | —(CH═CH)— | A-4 | 1 | —O— | 1 | 1 | 1 |
| II-38 | 4 | —SO3H | 4′ | —SO3H | —(CH═CH)— | A-4 | 1 | —NH— | 1 | 1 | 1 |
| II-39 | 4 | —SO3H | 4′ | —SO3H | —(CH═CH)— | A-4 | 1 | —NC2H5— | 1 | 1 | 1 |
| II-40 | 4 | —SO3H | 4′ | —SO3H | —(CH═CH)— | A-4 | 1 | —PCH3— | 1 | 1 | 1 |
| II-41 | 4 | —SO3H | 4′ | —SO3H | —(CH═CH)— | A-4 | 1 | —Si(CH3)2— | 1 | 1 | 1 |
| II-42 | 4 | —PO3H2 | 4′ | —PO3H2 | —(CH═CH)— | A-4 | 1 | — | 0 | 1 | 1 |
| II-43 | 4 | —PO3H2 | 4′ | —PO3H2 | —(CH═CH)— | A-4 | 1 | —S— | 1 | 1 | 1 |
| II-44 | 4 | —PO3H2 | 4′ | —PO3H2 | —(CH═CH)— | A-4 | 1 | —SO2— | 1 | 1 | 1 |
| II-45 | 4 | —PO3H2 | 4′ | —PO3H2 | —(CH═CH)— | A-4 | 1 | —Se— | 1 | 1 | 1 |
| II-46 | 4 | —PO3H2 | 4′ | —PO3H2 | —(CH═CH)— | A-4 | 1 | —O— | 1 | 1 | 1 |
| II-47 | 4 | —COOH | 4′ | —COOH | —(C≡C)— | A-4 | 1 | —NH— | 1 | 1 | 1 |
| II-48 | 4 | —COOH | 4′ | —COOH | —(C≡C)— | A-4 | 1 | —NC2H5— | 1 | 1 | 1 |
| II-49 | 4 | —COOH | 4′ | —COOH | —(C≡C)— | A-4 | 1 | —PCH3— | 1 | 1 | 1 |
| II-50 | 4 | —COOH | 4′ | —COOH | —(C≡C)— | A-4 | 1 | —Si(CH3)2— | 1 | 1 | 1 |

Pos*: Position

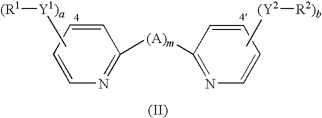

In each pyridine ring, a nitrogen atom is situated at the 1-position, and a carbon atom connecting to A is situated at the 2-position. The number of Ar corresponds to the number of the examples shown above.

In the above-described table, R¹ or R² preferably represents an acidic group, more preferably a carboxylic group. It is more preferable that both of them represent an acidic group, further preferably, a carboxylic group. The position for Y¹ or Y² is preferably 4 or 4′.

Y¹ or Y² preferably represents an ethylene group (—C═C—), and it is more preferable that both of them represent an ethylene group.

m is preferably 0 or 1, further preferably 0.

In the above-described table, (II-1) to (II-32) are preferable, (II-1) to (II-22) are more preferable, and (II-1) and (II-4) are further preferable.

Examples of the ligand (III) include compounds represented by the following formula and shown in Table 2.

TABLE 2

| Com- | R³ | | R⁴ | | | | | |
|---|---|---|---|---|---|---|---|---|
| pound | Pos* | Group | Pos* | Group | B | n | c | d |
| III-1 | 4 | —COOH | 4′ | —COOH | — | 0 | 1 | 1 |
| III-2 | 4 | —COOH | 4′ | —COOH | —S— | 1 | 1 | 1 |
| III-3 | 4 | —COOH | 4′ | —COOH | —SO2— | 1 | 1 | 1 |
| III-4 | 4 | —COOH | 4′ | —COOH | —Se— | 1 | 1 | 1 |
| III-5 | 3 | —COOH | 3′ | —COOH | — | 0 | 1 | 1 |
| III-6 | 4 | —SO3H | 4′ | —SO3H | — | 0 | 1 | 1 |
| III-7 | 4 | —SO3H | 4′ | —SO3H | —S— | 1 | 1 | 1 |
| III-8 | 4 | —SO3H | 4′ | —SO3H | —SO2— | 1 | 1 | 1 |
| III-9 | 4 | —SO3H | 4′ | —SO3H | —Se— | 1 | 1 | 1 |
| III-10 | 4 | —PO3H2 | 4′ | —PO3H2 | — | 0 | 1 | 1 |

Pos*: Position

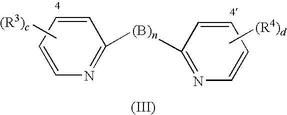

In the above-described table, R³ or R⁴ preferably represents an acidic group, more preferably a carboxylic group. It is more preferable that both of them represent an acidic group, further preferably, a carboxylic group. The position for R³ or R⁴ is preferably 4 or 4′.

n is preferably 0 or 1, more preferably 0.

In the above-described table, (III-1) to (III-5) are preferable, (III-1) to (III-4) are more preferable, and (III-1) is further preferable.

Examples of the ligand (IV) include compounds represented by the following formulae and shown in Tables 3 and 4.

TABLE 3

| | Y3═Y4 | | | | | |
|---|---|---|---|---|---|---|
| Compound | Position | UnsatHyca G** | Ar | Substitutent of Ar | B | n |
| IV-1 | 4, 4′ | —(CH═CH)— | A-1 | H | —S— | 1 |
| IV-2 | 4, 4′ | —(CH═CH)— | A-1 | —CH3 | —S— | 1 |
| IV-3 | 4, 4′ | —(CH═CH)— | A-1 | —CH2CH3 | —S— | 1 |
| IV-4 | 4, 4′ | —(CH═CH)— | A-1 | -n-Pr | —S— | 1 |
| IV-5 | 4, 4′ | —(CH═CH)— | A-1 | -i-Pr | —S— | 1 |
| IV-6 | 4, 4′ | —(CH═CH)— | A-1 | -n-Bu | —S— | 1 |
| IV-7 | 4, 4′ | —(CH═CH)— | A-1 | -t-Bu | —S— | 1 |
| IV-8 | 4, 4′ | —(CH═CH)— | A-1 | —C10H21 | —S— | 1 |
| IV-9 | 4, 4′ | —(CH═CH)— | A-1 | —OCH3 | —S— | 1 |
| IV-10 | 4, 4′ | —(C≡C)— | A-1 | —OCH3 | —S— | 1 |
| IV-11 | 4, 4′ | —(CH═CH)— | A-1 | —OPh | —S— | 1 |
| IV-12 | 4, 4′ | —(CH═CH)— | A-1 | —CH(—OCH2CH2O—) | —S— | 1 |
| IV-13 | 4, 4′ | —(CH═CH)— | A-1 | —OiPr | —S— | 1 |
| IV-14 | 4, 4′ | —(CH═CH)— | A-1 | —OH | —S— | 1 |
| IV-15 | 4, 4′ | —(CH═CH)— | A-1 | —N(CH3)2 | —S— | 1 |
| IV-16 | 4, 4′ | —(CH═CH)— | A-1 | —N(C2H5)2 | —S— | 1 |
| IV-17 | 4, 4′ | —(CH═CH)— | A-1 | —N(CH3)(C4H9) | —S— | 1 |
| IV-18 | 4, 4′ | —(CH═CH)— | A-1 | —NPh2 | —S— | 1 |
| IV-19 | 4, 4′ | —(CH═CH)— | A-1 | H | — | 0 |
| IV-20 | 4, 4′ | —(CH═CH)— | A-1 | —CH3 | — | 0 |
| IV-21 | 4, 4′ | —(CH═CH)— | A-1 | —CH2CH3 | — | 0 |
| IV-22 | 4, 4′ | —(CH═CH)— | A-1 | -n-Pr | — | 0 |
| IV-23 | 4, 4′ | —(CH═CH)— | A-1 | -i-Pr | — | 0 |
| IV-24 | 4, 4′ | —(CH═CH)— | A-1 | -n-Bu | — | 0 |
| IV-25 | 4, 4′ | —(CH═CH)— | A-1 | -t-Bu | — | 0 |
| IV-26 | 4, 4′ | —(CH═CH)— | A-1 | —C10H21 | — | 0 |
| IV-27 | 4, 4′ | —(CH═CH)— | A-1 | —OCH3 | — | 0 |
| IV-28 | 4, 4′ | —(CH═CH)— | A-1 | —OCH2CH3 | — | 0 |
| IV-29 | 4, 4′ | —(CH═CH)— | A-1 | —OPh | — | 0 |
| IV-30 | 4, 4′ | —(CH═CH)— | A-1 | —CH(—OCH2CH2O—) | — | 0 |
| IV-31 | 4, 4′ | —(CH═CH)— | A-1 | —OiPr | — | 0 |
| IV-32 | 4, 4′ | —(CH═CH)— | A-1 | —OH | — | 0 |
| IV-33 | 4, 4′ | —(CH═CH)— | A-1 | —N(CH3)2 | — | 0 |
| IV-34 | 4, 4′ | —(CH═CH)— | A-1 | —N(C2H5)2 | — | 0 |
| IV-35 | 4, 4′ | —(CH═CH)— | A-1 | —N(CH3)(C4H9) | — | 0 |
| IV-36 | 4, 4′ | —(CH═CH)— | A-1 | —NPh2 | — | 0 |
| IV-37 | 4, 4′ | —(CH═CH)— | A-2 | —OCH3 | —S— | 1 |
| IV-38 | 4, 4′ | —(OH═CH)— | A-3 | —OCH3 | —S— | 1 |
| IV-39 | 4, 4′ | —(CH═CH)— | A-4 | —OCH3 | —S— | 1 |
| IV-40 | 4, 4′ | —(CH═CH)— | A-5 | —OCH3 | —S— | 1 |
| IV-41 | 4, 4′ | —(CH═CH)— | A-6 | —OCH3 | —S— | 1 |
| IV-42 | 4, 4′ | —(CH═CH)— | A-7 | —OCH3 | —S— | 1 |
| IV-43 | 4, 4′ | —(OH═CH)— | A-8 | —OCH3 | —S— | 1 |
| IV-44 | 4, 4′ | —(CH═CH)— | A-9 | —OCH3 | —S— | 1 |
| IV-45 | 4, 4′ | —(CH═CH)— | A-10 | —OCH3 | —S— | 1 |
| IV-46 | 4, 4′ | —(CH═CH)— | A-11 | —OCH3 | —S— | 1 |
| IV-47 | 4, 4′ | —(CH═CH)— | A-12 | —OCH3 | —S— | 1 |
| IV-48 | 4, 4′ | —(CH═CH)— | A-13 | —OCH3 | —S— | 1 |

Y3═Y4

| Compound | Position | UnsatHyca G** | Ar | Substitutent of Ar | B | n | c | d |
|---|---|---|---|---|---|---|---|---|
| IV-49 | 4, 4′ | —(CH═CH)— | A-14 | —OCH3 | —S— | 1 | 1 | 1 |
| IV-50 | 4, 4′ | —(CH═CH)— | A-15 | —OCH3 | —S— | 1 | 1 | 1 |
| IV-51 | 4, 4′ | —(CH═CH)— | A-16 | —OCH3 | —S— | 1 | 1 | 1 |
| IV-52 | 4, 4′ | —(CH═CH)— | A-17 | —OCH3 | —S— | 1 | 1 | 1 |
| IV-53 | 4, 4′ | —(CH═CH)— | A-18 | —OCH3 | —S— | 1 | 1 | 1 |
| IV-54 | 4, 4′ | —(CH═CH)— | A-19 | —OCH3 | —S— | 1 | 1 | 1 |
| IV-55 | 4, 4′ | —(CH═CH)— | A-20 | —OCH3 | —S— | 1 | 1 | 1 |
| IV-56 | 4, 4′ | —(CH═CH)— | A-21 | —OCH3 | —S— | 1 | 1 | 1 |
| IV-57 | 4, 4′ | —(CH═CH)— | A-22 | —OCH3 | —S— | 1 | 1 | 1 |
| IV-58 | 4, 4′ | —(CH═CH)— | A-1 | —OCH3 | —SO2— | 1 | 1 | 1 |
| IV-59 | 4, 4′ | —(CH═CH)— | A-1 | —OCH3 | —Se— | 1 | 1 | 1 |
| IV-60 | 4, 4′ | —(CH═CH)— | A-1 | —OCH3 | —O— | 1 | 1 | i |
| IV-61 | 4, 4′ | —(CH═CH)— | A-1 | —OCH3 | —PEt- | 1 | 1 | 1 |
| IV-62 | 4, 4′ | —(CH═CH)— | A-1 | —OCH3 | —NEt- | 1 | 1 | 1 |
| IV-63 | 4, 4′ | —(CH═CH)— | A-1 | —OCH3 | —SiMe2- | 1 | 1 | 1 |
| IV-64 | 4, 4′ | —(CH═CH)— | A-1 | —OCH3 | —CEt2— | 1 | 1 | 1 |
| IV-65 | 6, 6′ | —(CH═CH)— | A-1 | —OCH3 | —S— | 1 | 1 | 1 |

UnsatHyca G**: Unsaturated Hydrocarbon Group

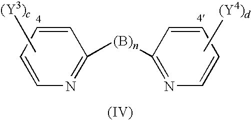

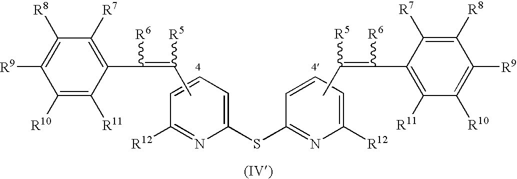

TABLE 4

| Compound | Y3; Pos* | Y4; Pos** | R⁵ | R⁶ | R⁷ | R⁸ | R⁹ | R¹⁰ | R¹¹ | R¹² |
|---|---|---|---|---|---|---|---|---|---|---|
| IV-66 | 4 | 4′ | H | H | H | H | —SCH3 | H | H | H |
| IV-67 | 4 | 4′ | H | H | H | H | —CF3 | H | H | H |
| IV-68 | 4 | 4′ | H | H | —OCH3 | H | —OCH3 | H | —OCH3 | H |
| IV-69 | 4 | 4′ | H | H | H | H | —OC2H4OC2H5 | H | H | H |
| IV-70 | 4 | 4′ | —CN | H | H | H | —OCH3 | H | H | H |
| IV-71 | 4 | 4′ | H | H | H | —OCH3 | H | —OCH3 | H | H |
| IV-72 | 4 | 4′ | H | H | H | —OCH3 | H | H | H | H |
| IV-73 | 4 | 4′ | H | H | —OCH3 | H | H | H | H | H |
| IV-74 | 4 | 4′ | H | H | —OCH3 | H | —OCH3 | H | H | H |
| IV-75 | 4 | 4′ | H | H | H | —CF3 | —OCH3 | H | H | H |
| IV-76 | 4 | 4′ | H | H | H | H | —OCH3 | H | H | —CH3 |

Y3; Pos*: Position of Y3
Y4; Pos**: Position of Y4

In the above-described tables, Y³ or Y⁴ preferably represents an ethylene group (—C═C—), and it is more preferable that both of them represent an ethylene group. The positions of the ethylene group are preferably 4 and 4′.

Ar is preferably A-1, and as the substituent for Ar, preferable are alkyl groups, aryloxy groups, alkoxy groups, dialkylamino groups and diarylamino groups, and more preferable are alkoxy groups.

n is preferably 0 or 1, more preferably 0.

In the above-described tables, (IV-1) to (IV-57), (IV-66) to (IV-76) are preferable, (IV-1) to (IV-36) and (IV-66) to (IV-76) are more preferable, and (IV-19) to (IV-36) are further preferable.

The complex compound (I) of the present invention is obtained by coordinating a ligand represented by the above-described formula (II) and a bidentate ligand to a metal atom.

In the complex compound (I) of the present invention, the center atom is a metal atom, and one of ligands is a ligand represented by the above-described formula (II). In the complex compounds (I′), (I″) and (I′″), bidentate ligands other than the ligand represented by the above-described formula (II) (for example, the above-described formulae (II), (III) or (IV)) or auxiliary ligands may be coordinated, and examples of the auxiliary ligand include isothiocyanate (—N═CS, hereinafter, referred to as NCS in some cases), thiocyanate hereinafter, referred to as SCN in some cases), diketonate, chloro, bromo, iodo, cyano, hydroxyl group and the like, and preferably, NCS or SCN.

When the auxiliary ligand is mono-valent, it may be present in the form of neutralization of charge, together with a counter anion such as a halogen anion.

A method of producing a complex compound (I) is explained by the case where the center metal atom is Ru as a example, [RuCl₂(p-cymene)]₂ is dissolved in an aprotic polar solvent such as N,N-dimethylformamide, and a ligand (II) and bidentate ligand are mixed in at about 40 to 180° C., then, if necessary, a salt which gives an auxiliary ligand is mixed in, and from the resultant reaction solution, a complex compound (I) is obtained by purification by re-crystallization, chromatography, and the like.

Here, as the Ru reagent, di-valent and tri-valent Ru reagents are used, and specific examples thereof include RuCl₃, RuCl₂(DMSO)₄ and the like.

Specific examples of the complex compound (I) include (I′), (I″), (I′″) and the like, and compounds (I-1) to (I-43) represented by the following formula and shown in Table 5, compounds (I-44) to (I-74) shown in Table 6, and compounds (I-75) to (I-141) shown in Table 7.

TABLE 5

| Compound | M | Ligand(1) | Ligand(2) | X₁═X₂ |
|---|---|---|---|---|
| I-1 | Ru | II-1 | II-1 | —NCS |
| I-2 | Ru | II-2 | II-2 | —NCS |
| I-3 | Ru | II-3 | II-3 | —NCS |
| I-4 | Ru | II-4 | II-4 | —NCS |
| I-5 | Ru | II-5 | II-5 | —NCS |
| I-6 | Ru | II-6 | II-6 | —NCS |
| I-7 | Ru | II-7 | II-7 | —NCS |
| I-8 | Ru | II-8 | II-8 | —NCS |
| I-9 | Ru | II-9 | II-9 | —NCS |
| I-10 | Ru | II-10 | II-10 | —NCS |
| I-11 | Ru | II-11 | II-11 | —NCS |
| I-12 | Ru | II-12 | II-12 | —NCS |
| I-13 | Ru | II-13 | II-13 | —NCS |
| I-14 | Ru | II-14 | II-14 | —NCS |
| I-15 | Ru | II-15 | II-15 | —NCS |
| I-16 | Ru | II-16 | II-16 | —NCS |
| I-17 | Ru | II-17 | II-17 | —NCS |
| I-18 | Ru | II-18 | II-18 | —NCS |
| I-19 | Ru | II-19 | II-19 | —NCS |
| I-20 | Ru | II-20 | II-20 | —NCS |
| I-21 | Ru | II-21 | II-21 | —NCS |
| I-22 | Ru | II-22 | II-22 | —NCS |
| I-23 | Ru | II-4 | II-1 | —NCS |
| I-24 | Ru | II-4 | II-2 | —NCS |
| I-25 | Ru | II-4 | II-3 | —NCS |
| I-26 | Ru | II-4 | II-5 | —NCS |
| I-27 | Ru | II-4 | II-6 | —NCS |
| I-28 | Ru | II-4 | II-7 | —NCS |
| I-29 | Ru | II-4 | II-8 | —NCS |
| I-30 | Ru | II-4 | II-9 | —NCS |
| I-31 | Ru | II-4 | II-10 | —NCS |
| I-32 | Ru | II-4 | II-11 | —NCS |
| I-33 | Ru | II-4 | II-12 | —NCS |
| I-34 | Ru | II-4 | II-13 | —NCS |
| I-35 | Ru | II-4 | II-14 | —NCS |
| I-36 | Ru | II-4 | II-15 | —NCS |
| I-37 | Ru | II-4 | II-16 | —NCS |
| I-38 | Ru | II-4 | II-17 | —NCS |
| I-39 | Ru | II-4 | II-18 | —NCS |
| I-40 | Ru | II-4 | II-19 | —NCS |
| I-41 | Ru | II-4 | II-20 | —NCS |
| I-42 | Ru | II-4 | II-21 | —NCS |
| I-43 | Ru | II-4 | II-22 | —NCS |

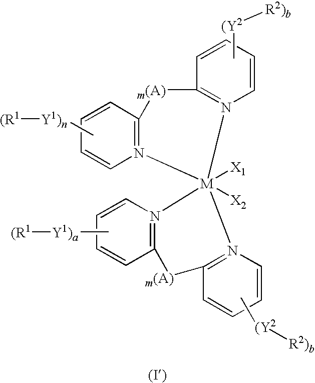

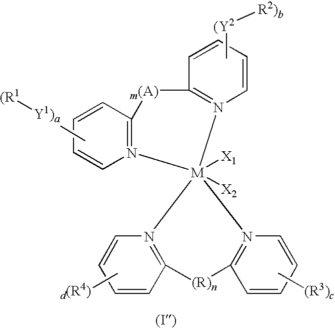

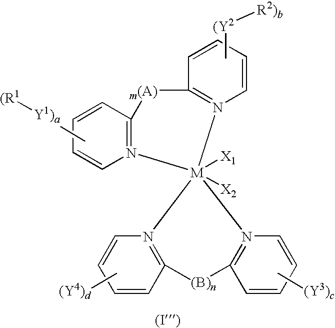

TABLE 6

| Compound | M | Ligand(1) | Ligand(2) | X₁ = X₂ |
|---|---|---|---|---|
| I-44 | Ru | II-1 | III-1 | -NCS |
| I-45 | Ru | II-2 | III-1 | -NCS |
| I-46 | Ru | II-3 | III-1 | -NCS |
| I-47 | Ru | II-4 | III-1 | -NCS |
| I-48 | Ru | II-5 | III-1 | -NCS |
| I-49 | Ru | II-6 | III-1 | -NCS |
| I-50 | Ru | II-7 | III-1 | -NCS |
| I-51 | Ru | II-8 | III-1 | -NCS |
| I-52 | Ru | II-9 | III-1 | -NCS |
| I-53 | Ru | II-10 | III-1 | -NCS |
| I-54 | Ru | II-11 | III-1 | -NCS |
| I-55 | Ru | II-12 | III-1 | -NCS |
| I-56 | Ru | II-13 | III-1 | -NCS |
| I-57 | Ru | II-14 | III-1 | -NCS |
| I-58 | Ru | II-15 | III-1 | -NCS |
| I-59 | Ru | II-16 | III-1 | -NCS |
| I-60 | Ru | II-17 | III-1 | -NCS |
| I-61 | Ru | II-18 | III-1 | -NCS |
| I-62 | Ru | II-19 | III-1 | -NCS |
| I-63 | Ru | II-20 | III-1 | -NCS |
| I-64 | Ru | II-21 | III-1 | -NCS |
| I-65 | Ru | II-22 | III-1 | -NCS |
| I-66 | Ru | II-4 | III-2 | -NCS |
| I-67 | Ru | II-4 | III-3 | -NCS |
| I-68 | Ru | II-4 | III-4 | -NCS |
| I-69 | Ru | II-4 | III-5 | -NCS |
| I-70 | Ru | II-4 | III-6 | -NCS |
| I-71 | Ru | II-4 | III-7 | -NCS |
| I-72 | Ru | II-4 | III-8 | -NCS |
| I-73 | Ru | II-4 | III-9 | -NCS |
| I-74 | Ru | II-4 | III-10 | -NCS |

TABLE 7

| Compound | M | Ligand(1) | Ligand(2) | X₁ = X₂ |
|---|---|---|---|---|
| I-75 | Ru | II-4 | IV-1 | -NCS |
| I-76 | Ru | II-4 | IV-2 | -NCS |
| I-77 | Ru | II-4 | IV-3 | -NCS |
| I-78 | Ru | II-4 | IV-4 | -NCS |
| I-79 | Ru | II-4 | IV-5 | -NCS |
| I-80 | Ru | II-4 | IV-6 | -NCS |
| I-81 | Ru | II-4 | IV-7 | -NCS |
| I-82 | Ru | II-4 | IV-8 | -NCS |
| I-83 | Ru | II-4 | IV-9 | -NCS |
| I-84 | Ru | II-4 | IV-10 | -NCS |
| I-85 | Ru | II-4 | IV-11 | -NCS |
| I-86 | Ru | II-4 | IV-12 | -NCS |
| I-87 | Ru | II-4 | IV-13 | -NCS |
| I-88 | Ru | II-4 | IV-14 | -NCS |
| I-89 | Ru | II-4 | IV-15 | -NCS |
| I-90 | Ru | II-4 | IV-16 | -NCS |
| I-91 | Ru | II-4 | IV-17 | -NCS |
| I-92 | Ru | II-4 | IV-18 | -NCS |
| I-93 | Ru | II-4 | IV-19 | -NCS |
| I-94 | Ru | II-4 | IV-20 | -NCS |
| I-95 | Ru | II-4 | IV-21 | -NCS |
| I-96 | Ru | II-4 | IV-22 | -NCS |
| I-97 | Ru | II-4 | IV-23 | -NCS |
| I-98 | Ru | II-4 | IV-24 | -NCS |
| I-99 | Ru | II-4 | IV-25 | -NCS |
| I-100 | Ru | II-4 | IV-26 | -NCS |
| I-101 | Ru | II-4 | IV-27 | -NCS |
| I-102 | Ru | II-4 | IV-28 | -NCS |
| I-103 | Ru | II-4 | IV-29 | -NCS |
| I-104 | Ru | II-4 | IV-30 | -NCS |
| I-105 | Ru | II-4 | IV-31 | -NCS |
| I-106 | Ru | II-4 | IV-32 | -NCS |
| I-107 | Ru | II-4 | IV-33 | -NCS |
| I-108 | Ru | II-4 | IV-34 | -NCS |
| I-109 | Ru | II-4 | IV-35 | -NCS |
| I-110 | Ru | II-4 | IV-36 | -NCS |
| I-111 | Ru | II-4 | IV-37 | -NCS |
| I-112 | Ru | II-4 | IV-38 | -NCS |
| I-113 | Ru | II-4 | IV-39 | -NCS |
| I-114 | Ru | II-4 | IV-40 | -NCS |
| I-115 | Ru | II-4 | IV-41 | -NCS |
| I-116 | Ru | II-4 | IV-42 | -NCS |
| I-117 | Ru | II-4 | IV-43 | -NCS |
| I-118 | Ru | II-4 | IV-44 | -NCS |
| I-119 | Ru | II-4 | IV-45 | -NCS |
| I-120 | Ru | II-4 | IV-46 | -NCS |
| I-121 | Ru | II-4 | IV-47 | -NCS |
| I-122 | Ru | II-4 | IV-48 | -NCS |
| I-123 | Ru | II-4 | IV-49 | -NCS |
| I-124 | Ru | II-4 | IV-50 | -NCS |
| I-125 | Ru | II-4 | IV-51 | -NCS |
| I-126 | Ru | II-4 | IV-52 | -NCS |
| I-127 | Ru | II-4 | IV-53 | -NCS |
| I-128 | Ru | II-4 | IV-54 | -NCS |
| I-129 | Ru | II-4 | IV-55 | -NCS |
| I-130 | Ru | II-4 | IV-56 | -NCS |
| I-131 | Ru | II-4 | IV-57 | -NCS |
| I-132 | Ru | II-4 | IV-58 | -NCS |
| I-133 | Ru | II-4 | IV-59 | -NCS |
| I-134 | Ru | II-4 | IV-60 | -NCS |
| I-135 | Ru | II-4 | IV-61 | -NCS |
| I-136 | Ru | II-4 | IV-62 | -NCS |
| I-137 | Ru | II-4 | IV-63 | -NCS |
| I-138 | Ru | II-4 | IV-64 | -NCS |
| I-139 | Ru | II-4 | IV-65 | -NCS |
| I-140 | Ru | II-1 | IV-9 | -NCS |
| I-141 | Ru | II-5 | IV-9 | -NCS |

In the table 5, (I-4) and (I-23) to (I-43) are preferable. In the table 6, (I-47) and (I-66) to (I-74) are preferable, (I-47) and (I-66) to (I-69) are more preferable, (I-47) and (I-66) to (I-68) are further preferable. In the table 7, (I-75) to (I-131) are preferable, (I-75) to (I-110) are more preferable, (I-93) to (I-110) are further preferable.

As the complex compound (I), particularly, compounds in which R¹—Y¹— and R²—Y²— are groups represented by the formula (V″) and m=0 are preferable.

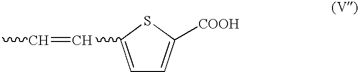

The photosensitizing coloring matter of the present invention is a coloring matter containing the complex compound (I) of the present invention. The coloring matter may be one complex compound (I) or a mixture of several complex compounds (I), or a mixture with a complex compound of different kind.

As the coloring matter which may be mixed with a complex compound (I), metal complexes, organic coloring matters and the like showing an absorption wavelength of from around 300 to 700 nm, are listed.

Specific examples of the metal complex which may be mixed include metal phthalocyanines such as copper phthalocyanine and titanyl phthalocyanine, chlorophyll, hemin, and complexes of ruthenium, osmium, iron, zinc and the like described in JPH01-220380-A and JPH05-504023-A, and the like.

Examples of the above-described ruthenium complex include
cis-bis(isothiocyanate)bis(2,2′-bipyridyl-4,4′-dicarboxylate)-ruthenium(II) bis-tetrabutylammonium,
cis-bis(isothiocyanate)bis(2,2′-bipyridyl-4,4′-dicarboxylate)-ruthenium(II),
tris(isothiocyanate)-ruthenium(II)-2,2′:6′,2″-terpyridine-4,4′,4″-tricarboxylic acid tris-tetrabutylammonium,
cis-bis(isothiocyanate)(2,2′-bipyridyl-4,4′-dicarboxylate)(2,2′-bipyridyl-4,4′-dinonyl)-ruthenium(II), and the like.

Examples of the organic coloring matter include metal-free phthalocyanine, cyanine coloring matters, merocyanine coloring matters, xanthene coloring matters, triphenylmethane coloring matter, organic coloring matter such as indoline, and the like.

Specific examples of the cyanine coloring matter include NK1194, NK3422 (all manufactured by Nippon Kanko Shikiso Kenkyusho K.K.), and the like.

Specific examples of the merocyanine coloring matter include NK2426 and NK2501 (all manufactured by Nippon Kanko Shikiso Kenkyusho K.K.).

Examples of the xanthene coloring matter include uranin, eosin, rose bengal, rhodamine B, dibromofluorescein and the like.

Examples of the triphenylmethane coloring matter include malachite green and crystal violet.

Examples of the coumarin coloring matter include compounds containing structural portions shown below such as NKX8i-2677 (manufactured by Hayashibara Biochemical Labs., Inc.) and the like.

Examples of the organic coloring matter such as indoline and the like include compounds containing structural portions shown below such as D-149 (manufactured by Mitsubishi Paper Mills Limited) and the like.

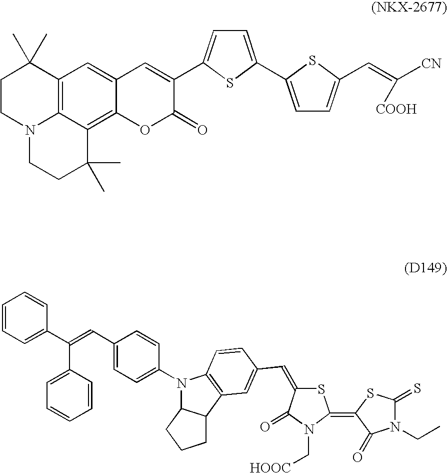

The photoelectric conversion device of the present invention is a device containing an electroconductive substrate and a semiconductor fine particle layer having a photosensitizing coloring matter containing a complex compound (I) of the present invention adsorbed thereon, and the adsorbed photosensitizing coloring matter is capable of absorbing also light energy of long wavelength of 700 nm or more.

The photoelectric conversion device can be used in an optical sensor which is sensitized to a wavelength of 700 nm or more as the absorption wavelength of a photosensitizing coloring matter containing a complex compound (I) of the present invention, or in a photoelectrochemical battery described later, and the like.

The primary particle size of the semiconductor fine particles used in the photoelectric conversion device of the present invention is usually about 1 to 5000 nm, preferably about 5 to 300 nm. Aiming at improvement in photoelectric conversion efficiency by reflection, semiconductor particles of different primary particle sizes may be mixed in. Further, fine particles in the form of tuber or of hollow shape may be used.

Examples of the semiconductor fine particles include metal oxides such as titanium oxide, tin oxide, zinc oxide, iron oxide, tungsten oxide, zirconium oxide, hafnium oxide, strontium oxide, indium oxide, cerium oxide, yttrium oxide, lanthanum oxide, vanadium oxide, niobium oxide, tantalum oxide, gallium oxide, nickel oxide, strontium titanate, barium titanate, potassium niobate and sodium tantalate;

metal halides such as silver iodide, silver bromide, copper iodide and copper bromide; metal sulfides such as zinc sulfide, titanium sulfide, indium sulfide, bismuth sulfide, cadmium sulfide, zirconium sulfide, tantalum sulfide, molybdenum sulfide, silver sulfide, copper sulfide, tin sulfide, tungsten sulfide and antimony sulfide;
metal selenides such as cadmium selenide, zirconium selenide, zinc selenide, titanium selenide, indium selenide, tungsten selenide, molybdenum selenide, bismuth selenide and lead selenide;
metal tellurides such as cadmium telluride, tungsten telluride, molybdenum telluride, zinc telluride and bismuth telluride;
metal phosphides such as zinc phosphide, gallium phosphide, indium phosphide and cadmium phosphide;
gallium arsenide, copper-indium-selenide, copper-indium-sulfide, silicon, germanium and the like.

Furthermore, mixtures of two or more components such as zinc oxide/tin oxide and tin oxide/titanium oxide may also be used.

Among them, metal oxides such as titanium oxide, tin oxide, zinc oxide, iron oxide, tungsten oxide, zirconium oxide, hafnium oxide, strontium oxide, indium oxide, cerium oxide, yttrium oxide, lanthanum oxide, vanadium oxide, niobium oxide, tantalum oxide, gallium oxide, nickel oxide, strontium titanate, barium titanate, potassium niobate, sodium tantalate, zinc oxide/tin oxide and tin oxide/titanium oxide are preferable since these are relatively inexpensive and easily available, and are also easily dyed with a coloring matter, and particularly, titanium oxide is suitable.

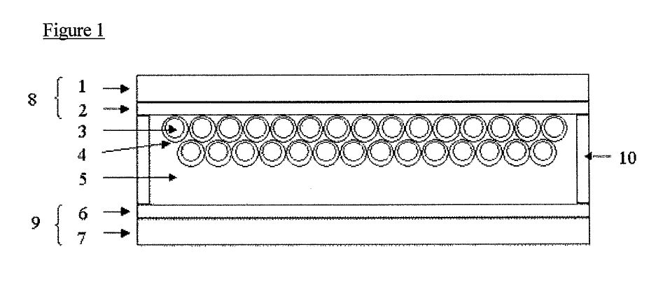

As the electroconductive substrate (8 and 9 in FIG. 1) to be used in the photoelectric conversion device of the present invention, an electroconductive substance itself, or a laminate of a substrate and an electroconductive substance can be used.

Examples of the electroconductive substrate include metals such as platinum, gold, silver, copper, aluminum, rhodium, indium, titanium and palladium, iron, alloys of said metals, electroconductive metal oxides such as indium-tin complex oxide and tin oxide doped with fluorine; carbon, electroconductive polymers such as polyethylenedioxythiophene (PEDOT) and polyaniline.

The electroconductive polymer may be doped with, for example, p-toluenesulfonic acid and the like.

Those having a texture structure on the surface are preferable for confining incident light to effectively utilize the light.

The electroconductive layer (2, 6 in FIG. 1) advantageously has lower resistance as much as possible, and preferably has higher transmittance (transmittance is 80% or more at the side longer than 350 nm).

As the electroconductive substrate (8 and 9 in FIG. 1), glass or plastic substrates coated with an electroconductive metal oxide are preferable. Among them, electroconductive glass laminated with an electroconductive layer composed of tin dioxide doped with fluorine is particularly preferable. In the case of plastic substrate, cyclic polyolefins (COP) such as ARTON (registered trademark of JSR), ZEONOR (registered trademark of ZEON Corporation), APEL (registered trademark of Mitsui Chemical Co., Ltd.), TOPAS (registered trademark of Ticona) and the like; polyethylene terephthalate (PET), polyethylene naphthalate (PEN), polyphenylene sulfide (PPS), polycarbonate (PC), polypropylene (PP), polyimide (PI), triacetylcellulose (TAC), syndiotactic polystyrene (SPS), polyarylate (PAR), polyether sulfone (PES), polyether imide (PEI), polysulfone (PSF), polyamide (PA) and the like are mentioned.

Among them, electroconductive PET laminated with an electroconductive layer composed of indium-tin complex oxide is particularly preferable since it has low resistance, shows excellent transmittance and is easily available.

Examples of the method for forming a semiconductor fine particle layer on an electroconductive substrate include a method in which a thin film of semiconductor fine particles is formed on an electroconductive substrate directly by spraying and the like; a method in which a semiconductor fine particle thin film is deposited electrically using an electroconductive substrate as an electrode; a method in which a slurry of semiconductor fine particles is applied on an electroconductive substrate, then, dried, hardened or calcined; and the like.

As the method of applying a slurry of semiconductor fine particles on an electroconductive substrate, for example, means such as doctor blade, squeezer, spin coater, dip coater, screen printing device and the like are mentioned.

In the case of this method, the average particle size of semiconductor fine particles in the slurry in the dispersed condition is preferably 0.01 μm to 100 μm.

As the dispersion medium for dispersing a slurry, those capable of dispersing semiconductor fine particles may be used, and mentioned are water, or organic solvents such as alcohol solvents e.g. ethanol, isopropanol, t-butanol, terpineol and the like; ketone solvents e.g. acetone, and the like. These water and organic solvents may be used in admixture. The dispersion liquid may contain a polymer such as polyethylene glycol; surfactant such as Triton-X; organic or inorganic acids such as acetic acid, formic acid, nitric acid and hydrochloric acid; chelating agents such as acetylacetone.

The electroconductive substrate carrying thereon an applied slurry is calcined, and the calcination temperature is lower than the melting point (or softening point) of a base material such as a thermoplastic resin and the like, and usually, the upper limit of the calcination temperature is 900° C., and preferably the temperature is not higher than 600° C. The calcination time is usually within 10 hours. The thickness of the semiconductor fine particle layer on the electroconductive substrate is usually 1 to 200 μm, preferably 5 to 50 μm.

As the method for forming the semiconductor fine particle layer at relatively low temperature on the electroconductive substrate, there are mentioned a Hydrothermal method in which a hydrothermal treatment is performed to form a porous semiconductor fine particle layer (Coloring Matter Sensitized Photoelectrochemical Battery for Practical Applications, second lecture (Hideki Minoura), p. 63-65, published by NTS (2003)), a migration electrodeposition method in which a dispersion of semiconductor particles dispersed is electrically deposited on a substrate (T. Miyasaka et al., Chem. Lett., 1250 (2002), a press method in which a semiconductor paste is applied on a substrate, and dried, then, pressed (Coloring Matter Sensitized Photoelectrochemical Battery for Practical Applications, 12-th lecture (Takehiko Ban), p. 312-313, published by NTS (2003)), and the like.

On the surface of the semiconductor fine particle layer, a chemical plating treatment using a titanium tetrachloride aqueous solution or an electrochemical plating treatment using a titanium trichloride aqueous solution may be performed. By this treatment, it becomes possible to increase the surface area of semiconductor fine particles, to enhance the purity around semiconductor fine particles, to cover impurities such as iron and the like present on the surface of semiconductor fine particles, or to enhance attachment and connection properties of semiconductor fine particles.

Semiconductor fine particles preferably have a larger surface area so as to adsorb a larger amount of coloring matter for photoelectric conversion device. Therefore, the surface area under the condition of application of a semiconductor fine particle layer on a substrate is preferably 10-fold or more, further preferably 100-fold or more with respect to the projected area. The upper limit thereof is usually about 1000-fold.

The semiconductor fine particle layer is not limited to a single layer composed of one kind of fine particles, and several layers of different particle sizes may be laminated.

As the method for adsorbing the photosensitizing coloring matter of the present invention on semiconductor fine particles, a method in which well-dried semiconductor fine particles are immersed for about 1 minute to 24 hours in a solution of the photosensitizing coloring matter of the present invention is used. Adsorption of the photosensitizing coloring matter may be carried out at room temperature, or may be carried out under reflux with heat. Adsorption of the photosensitizing coloring matter may be carried out before application of semiconductor fine particles, or carried out after application thereof, or alternatively, semiconductor fine particles and photosensitizing coloring matter may be simultaneously applied and adsorbed, however, it is preferable to adsorb the photosensitizing coloring matter on the semiconductor fine particle film after application. Adsorption of the photosensitizing coloring matter in the case of heat-treatment of the semiconductor fine particle layer is preferably carried out after the heat-treatment, and particularly preferable is a method in which the photosensitizing coloring matter is adsorbed quickly after the heat-treatment and before adsorption of water onto the surface of the fine particle layer.

For suppressing decrease in the sensitizing effect due to floating of the photosensitizing coloring matter not adhered to semiconductor fine particles, it is desirable that un-adsorbed photosensitizing coloring matter is removed by washing.

The photosensitizing coloring matter to be adsorbed may be used singly, or several photosensitizing coloring matters may be used in admixture. In the case of photoelectrochemical battery use, it is preferable to select the photosensitizing coloring matter to be mixed so as to widen as much as possible the photoelectric conversion wavelength region of an irradiation light such as solar light and the like. The adsorption amount of the photosensitizing coloring matter onto semiconductor fine particles is preferably 0.01 to 1 mmol with respect to 1 g of the semiconductor fine particles. Such amounts of coloring matter are preferable since a sensitizing effect on the semiconductor fine particles is obtained sufficiently, and there occurs a tendency of suppression of decrease in the sensitizing effect due to floating of the photosensitizing coloring matter not adhered to the semiconductor fine particles.

For the purpose of suppressing mutual actions such as gathering, aggregation and the like between photosensitizing coloring matters, a colorless compound may be co-adsorbed. As hydrophobic compounds to be co-adsorbed, steroid compounds having a carboxyl group (for example, chenodeoxycholic acid) and the like are mentioned. For the purpose of promoting removal of an excess of photosensitizing coloring matter, the surface of semiconductor fine particles may be treated using amines after the photosensitizing coloring matter is adsorbed. Preferable amines include pyridine, 4-tert-butylpyridine, polyvinylpyridine and the like. When these are in the form of a liquid, these may be used as they are, and when in the form of a solid, these may be dissolved in an organic solvent.

The photoelectrochemical battery of the present invention contains a photoelectric conversion device, charge moving layer and counter electrode, and is capable of converting light into electricity. In the photoelectrochemical battery, usually, a photoelectric conversion device, charge moving layer and counter electrode are laminated sequentially, and the electroconductive substrate of the photoelectric conversion device is attached to the counter electrode, thereby, charge moves, that is, power generation occurs.

Other examples of the photoelectrochemical battery include a photoelectrochemical battery having a plural number of lamination parts composed of a photoelectric conversion device and a charge moving layer, and having one counter electrode, a photoelectrochemical battery having a plural number of photoelectric conversion devices, one charge moving layer, and one counter electrode laminated, and the like.

The photoelectrochemical battery is roughly classified into a wet photoelectrochemical battery and a dry photoelectrochemical battery. In the wet photoelectrochemical battery, the charge moving layer to be contained is a layer composed of an electrolytic solution, and usually, the electrolytic solution is filled as the charge moving layer between the photoelectric conversion device and the counter electrode.

As the dry photoelectrochemical battery, for example, batteries in which a charge moving layer between a photoelectric conversion device and a counter electrode is composed of a solid hole transporting material are mentioned.

One embodiment of the photoelectrochemical battery is shown in FIG. 1. There exists an electroconductive substrate 8, a counter electrode 9 facing the electroconductive substrate 8, and a semiconductor fine particle layer 3 having a coloring matter 4 for photoelectric conversion device adsorbed thereon, between the electroconductive substrate 8 and the counter electrode 9. In the case of wet photoelectric conversion device, the semiconductor fine particle layer 3 is filled with an electrolytic solution 5, and sealed with a sealant 10.

The above-described electroconductive substrate 8 is composed of a substrate 1 and an electroconductive layer 2 in sequence from the upper side. The counter electrode 9 is composed of a substrate 7 and an electroconductive layer 6 in sequence from the lower side.

When the photoelectrochemical battery of the present invention is in wet mode, examples of an electrolyte used in the electrolytic solution contained in the charge moving layer include a combination of I₂ and various iodides, a combination of Br₂ and various bromides, a combination of metal complexes of ferrocyanate-ferricyanate, a combination of metal complexes of ferrocene-ferricinium ion, a combination of sulfur compounds of alkylthiol-alkyl disulfide, a combination of alkyl viologen and reduced substance thereof, a combination of polyhydroxybenzenes and oxides thereof, and the like.

Examples the iodide to be combined with I₂ include metal iodides such as LiI, NaI, KI, CsI and CaI₂; iodine salts of tetra-valent imidazolium compounds such as 1-propyl-3-methylimidazolium iodide and 1-propyl-2,3-dimethylimidazolium iodide; iodine salts of tetra-valent pyridinium compounds; iodine salts of tetraalkylammonium compounds; and the like.

Examples of the bromide to be combined with Br₂ include metal bromides such as LiBr, NaBr, KBr, CsBr and CaBr₂; bromine salts of tetra-valent ammonium compounds such as tetraalkylammonium bromide and pyridinium bromide.

Examples of the alkyl viologen include methyl viologen chloride, hexyl viologen bromide, benzyl viologen tetrafluoroborate and the like, and examples of the polyhydroxybenzenes include hydroquinone, naphthohydroquinone and the like.

As the electrolyte, particularly preferable are combinations of I₂ and at least one iodide selected from the group consisting of metal iodides, iodine salts of tetra-valent imidazolium compounds, iodine salts of tetra-valent pyridinium compounds, and iodine salts of tetraalkylammonium compounds.

Organic solvents used in the above-described electrolytes include nitrile solvents such as acetonitrile, methoxyacetonitrile and propionitrile; carbonate solvents such as ethylene carbonate and propylene carbonate; 1-methyl-3-propylimidazonium iodide and 1-methyl-3-hexylimidazonium iodide; ionic liquids such as 1-ethyl-3-methylimidazolium-bis(trifluoromethanesulfonic acid)imide; lactone solvents such as γ-butyrolactone; amide solvents such as N,N-dimethylformamide. These solvents may be gelled with polyacrylonitrile, polyvinylidene fluoride, poly-4-vinylpyridine, or a low molecular weight gelling agent shown in Chemistry Letters, 1241 (1998).

When the photoelectrochemical battery of the present invention is in dry mode, the solid hole transporting material to be used in the charge moving layer includes p-type inorganic semiconductors containing mono-valent copper such as CuI and CuSCN; and electroconductive polymers such as aromatic amines as shown in Synthetic Metal, 89, 215 (1997) and Nature, 395, 583 (1998); polythiophene and derivatives thereof; polypyrrole and derivatives thereof; polyaniline and derivatives thereof; poly(p-phenylene) and derivatives thereof; poly(p-phenylenevinylene) and derivatives thereof.

The counter electrode constituting the photoelectrochemical battery of the present invention is an electrode having electric conductivity, and the same substrate as the above-described electroconductive substrate may be used for maintaining strength and improving sealing property.

For reaching of light to the semiconductor fine particle layer on which a coloring matter for photoelectric conversion device has been adsorbed, at least one of the above-described electroconductive substrate and counter the electrode is usually substantially transparent. In the photoelectric conversion device of the present invention, it is preferable that the electroconductive substrate having the semiconductor fine particle layer is transparent, and incident light is guided from the side of the electroconductive substrate. In such case, it is preferable that a counter electrode has a property of being capable of reflecting light.

As the counter electrode 9 of the photoelectrochemical battery, for example, there can be used glass and plastics vapor-deposited with metals, carbon, electroconductive oxides and the like. Specifically, the counter electrode can also be produced by forming an electroconductive layer by a method such as vapor deposition and sputtering so as to obtain a thickness of 1 mm or less, preferably a thickness in the range of 5 nm to 100 μm. In the present invention, it is preferable to use glass vapor-deposited with platinum or carbon, or counter electrodes having an electroconductive layer formed by vapor deposition or sputtering.

For preventing leakage or transpiration of an electrolytic solution in the photoelectrochemical battery, a sealant may be used to attain sealing. As the sealant, there can be used ionomer resins such as HIMILAN (manufactured by Du-Pont Mitsui Polychemical); glass frit; hot melt adhesives such as SX1170 (manufactured by Solaronix); adhesives such as Amosil 4 (manufactured by Solaronix); BYNEL (manufactured by Du-Pont).

The present invention will be illustrated further in detail by examples mentioned below, but the present invention is not limited to these examples.

### Production Example 1

### Production Example of Compound (I-47)

A reaction vessel was purged with nitrogen, and 29 mg (0.05 mmol, purchased from Kanto Chemical Co., Inc.) of [RuCl₂(p-cymene)]₂ and 50 ml of N,N-dimethylformamide were charged, they were stirred at room temperature, and dissolution thereof was confirmed. Thereafter, 24 mg (0.10 mmol, purchased from AVOCADO) of compound III-1 was charged and the mixture was stirred at 70° C. for 4 hours, and disappearance of the raw materials was confirmed by HPLC. Then, 46 mg (0.10 mmol) of compound II-4 (prepared according to description of Monatshefte fuer Chemie (1988), 119(1), 1 to 15) was charged, and the temperature was raised up to 130° C. and the mixture was stirred for 6 hours. Thereafter, a solution prepared by dissolving 146 mg (1.50 mmol) of potassium thiocyanate in 3 ml of water was charged, and the mixture was stirred at 120° C. for 5 hours.

After the reaction, the reaction solution was concentrated by an evaporator, a highly-purified purple solid was separated and obtained from the concentrated residue by high performance liquid chromatography. The obtained solid was identified to be an intended compound (I-47, molecular weight 922) by ESI-MS.

Compound (I-47) ESI-MS (m/z) m/z=922 M⁺

### Example 1

A titanium oxide dispersion Ti-Nanoxide T/SP (trade name, manufactured by Solaronix) was applied using a screen printer on the electroconductive surface of electroconductive glass having a tin oxide film doped with fluorine (manufactured by Nippon Sheet Glass Co., Ltd., 10 Ω/□) as an electroconductive substrate, then, the coated glass was calcined at 500° C., and cooled, to laminate a semiconductor fine particle layer on the electroconductive substrate. Subsequently, it was immersed for 16 hours in a solution of the compound (I-47) (concentration is 0.0003 mol/liter, solvent is ethanol, and chenodeoxycholic acid is added at 0.01 mol/liter) and taken out from the solution, then, washed with acetonitrile, then, dried naturally to obtain a laminate (area of titanium oxide electrode is 24 mm²) composed of the electroconductive substrate and the semiconductor fine particle layer having the photosensitizing coloring matter adsorbed thereon. Then, around the layer, a polyethylene terephthalate film of 25 μm thickness was placed as a spacer, then, the layer was impregnated with an electrolytic solution (solvent is acetonitrile, iodine concentration in the solvent is 0.05 mol/liter, lithium iodide concentration in the solvent is 0.1 mol/liter, concentration in the solvent of 4-t-butylpyridine is 0.5 mol/liter, and concentration in the solvent of 1-propyl-2,3-dimethylimidazolium iodide is 0.6 mol/liter). Finally, a platinum-deposited glass as a counter electrode was laminated, to obtain a photoelectrochemical battery in which the electroconductive substrate, the semiconductor fine particle layer having the photosensitizing coloring matter adsorbed thereon, and the counter electrode of the electroconductive substrate were laminated and the electrolytic solution was impregnated between the electroconductive substrate and the counter electrode. Thus manufactured photoelectrochemical battery was subjected to IPCE measurement using an IPCE (incident photon-to-current efficiency) measuring apparatus (manufacture by Bunkoh Keiki Co., Ltd.).

IPCE of the photoelectric conversion device obtained in Example 1 is shown in Table 8.

### Production Example 2

### Production Example of Compound (I-83)

A reaction vessel was purged with nitrogen, and 27 mg (0.04 mmol, purchased from Kanto Chemical Co., Inc.) of [RuCl₂(p-cymene)]₂ and 8 ml of N,N-dimethylformamide were charged, they were stirred at room temperature, and dissolution thereof was confirmed. Thereafter, 40 mg (0.09 mmol) of compound (IV-9) was charged and the mixture was stirred at 60° C. for 30 minutes, and disappearance of the raw materials was confirmed by HPLC. Then, 41 mg (0.09 mmol) of compound II-4 (prepared according to description of Monatshefte fuer Chemie (1988), 119(1), 1 to 15) was charged, and the temperature was raised up to 100° C. and one hour later, the mixture was heated up to 140° C. and stirred for 2 hours. Thereafter, a solution prepared by dissolving 129 mg (1.33 mmol) of potassium thiocyanate in 1.2 ml of water was charged, and the mixture was stirred at 60° C. for 1 hour, then, heated up to 105° C. and stirred with heating for 1 hour.

After the reaction, the reaction solution was concentrated by an evaporator, and a highly-purified purple solid was separated and obtained from the concentrated residue by high performance liquid chromatography. The obtained solid was identified to be an intended compound (I-83, molecular weight 1130) by ESI-MS.

Compound (I-83) ESI-MS (m/z) m/z=1130 M⁺

### Example 2

A photoelectrochemical battery was obtained in the same manner as in Example 1 except that the compound I-83 was used instead of the compound I-47 as a photosensitizing coloring matter. Then, IPCE was measured in the same manner as in Example 1. The results are summarized in Table 8.

### Production Example 3

### Production Example of Compound (I-101)

A compound I-101 was produced in the same manner as in Production Example 2 except that the compound IV-27 was used instead of the compound IV-9. The obtained solid was identified to be an intended compound (I-101, molecular weight 914) by ESI-MS.

Compound (I-101) ESI-MS (m/z) m/z=914 M⁺

### Example 3

A photoelectrochemical battery was obtained in the same manner as in Example 1 except that the compound I-101 was used instead of the compound I-47 as a photosensitizing coloring matter. Then, IPCE was measured in the same manner as in Example 1. The results are summarized in Table 8.

### Comparative Example 1

A photoelectrochemical battery was obtained in the same manner as in Example 1 except that cis-bis(isothiocyanate)bis(2,2′-bipyridyl-4,4′-dicarboxylate)-ruthenium(II) (compound (I)) was used as a photosensitizing coloring matter. Then, IPCE was measured in the same manner as in Example 1. The results are summarized in Table 8.

TABLE 8

| | | | | Comparative |
|---|---|---|---|---|
| | Example 1 | Example 2 | Example 3 | Example 1 |
| Compound | (I-47) | (I-83) | (I-101) | (1) |
| IPCE (700 nm) | 22.8% | 7.3% | 41.9% | 6.5% |
| IPCE (750 nm) | 5.1% | 1.4% | 15.5% | 1.3% |
| IPCE (800 nm) | 0.71% | 0.10% | 2.28% | 0.08% |

The photoelectrochemical batteries obtained in Example 1, 2 and 3 were subjected to measurement of conversion efficiency using a solar simulator (type YSS-80A) manufactured by Yamashita Denso Corporation. When measured, the light intensity was 100 mW/cm².

Letting a conversion efficiency of the photoelectrochemical battery obtained in Example 2 be 1, relative values of conversion efficiencies of the photoelectrochemical batteries obtained in Example 1 and Example 3 are shown in Table 9.

TABLE 9

| | Example 1 | Example 2 | Example 3 |
|---|---|---|---|
| Compound | (I-47) | (I-83) | (I-101) |
| Relative Values of | 1.37 | 1.00 | 1.18 |
| Conversion Efficiency | | | |

### INDUSTRIAL APPLICABILITY

The complex compound (I) of the present invention is excellent in photoelectric conversion not only in the visible light region but also in the near infrared region, and used suitably as a photosensitizing coloring matter. A photoelectric conversion device containing this compound is excellent in photoelectric conversion efficiency, thus, it can be used in a solar battery using solar light, or a photoelectrochemical battery using artificial light in tunnels and houses. The photoelectric conversion device can be used as an optical sensor since electric current flows in this device when irradiated with light.

1. A complex compound (I) comprising a ligand represented by the formula (II) below, a bidentate ligand and a metal atom, 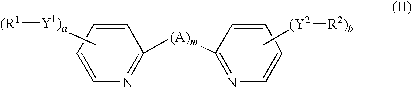
wherein, in the formula, Y¹ and Y² each independently contain an unsaturated aliphatic hydrocarbon group and an aromatic ring; R¹ and R² each independently represent a salt of an acidic group or an acidic group; A represents a group containing a nitrogen atom, an oxygen atom, a carbon atom, a silicon atom, a sulfur atom or a selenium atom; and m, a, and b each independently represent an integer of 0 to 2, while satisfying a+b≧1.

2. The complex compound according to claim 1, wherein the bidentate ligand is the ligand represented by the formula (II),

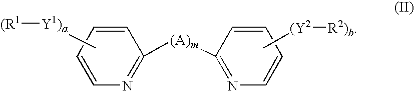

3. The complex compound according to claim 1, wherein the bidentate ligand is a ligand represented by the formula (III), 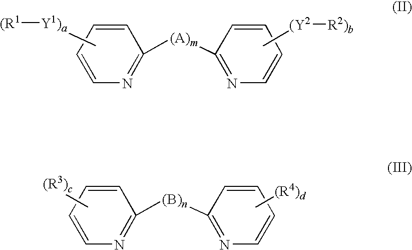
wherein, in the formulae, Y¹ and Y² each independently contain an unsaturated aliphatic hydrocarbon group and an aromatic ring; R¹, R², R³ and R⁴ each independently represent a salt of an acidic group or an acidic group; A and B each independently represent a group containing a nitrogen atom, an oxygen atom, a carbon atom, a silicon atom, a sulfur atom or a selenium atom; and m, n, a, b, c and d each independently represent an integer of 0 to 2, while satisfying a+b≧1 and c+d≧1.

4. The complex compound according to claim 1, wherein the bidentate ligand is a ligand represented by the formula (IV), 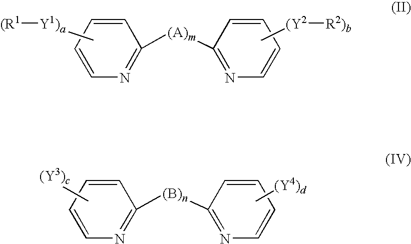
wherein, in the formulae, R¹ and R² each independently represent a salt of an acidic group or an acidic group; Y¹, Y², Y³ and Y⁴ each independently represent a group containing an unsaturated aliphatic hydrocarbon group and an aromatic ring; A and B each independently represent a group containing a nitrogen atom, an oxygen atom, a carbon atom, a silicon atom, a sulfur atom or a selenium atom; and m, n, a, b, c and d each independently represent an integer of 0 to 2, while satisfying a+b≧1 and c+d≧1.

5. The complex compound according to claim 1, wherein either of R¹ and R² is an acidic group.

6. The complex compound according to claim 5, wherein the acidic group is at least one group selected from the group consisting of carboxyl group, sulfonic group, squaric group, phosphoric group and boric group.

7. The complex compound according to claim 6, wherein the acidic group is a carboxyl group.

8. The complex compound according to claim 1, wherein either of R' and R² is a salt of an acidic group.

9. The complex compound according to claim 8, wherein the salt of the acidic group is a salt with an organic base.

10. The complex compound according to claim 1, wherein Y¹, Y², Y³ and Y⁴ are each independently a group represented by the formula (V) or the formula (V′), 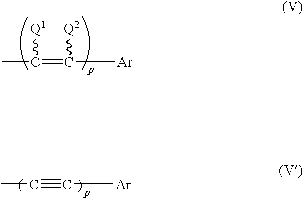
wherein, in the formulae (V) and (V′), Ar represents an optionally substituted aryl group; Q¹ and Q² each independently represent a hydrogen atom, an alkyl group having 1 to 20 carbon atoms, an aryl group having 6 to 20 carbon atoms, or a cyano group; and p represents an integer of 1 to 3.

11. The complex compound according to claim 10, wherein Y¹ and Y² are a group represented by the formula (V) defined in claim 10, Q¹ and Q² are a hydrogen atom, Ar is an optionally substituted thiophene ring, and p is 1.

12. The complex compound according to claim 1, wherein A is each independently at least one selected from the group consisting of —N(R⁵)—, —O—, —C(R⁵)(R⁶)—, —Si(R⁵)(R⁶)—, —S—, —SO—, —SO₂— and —Se—,
wherein R⁵ and R⁶ each independently represent a hydrogen atom, an alkyl group having 1 to 20 carbon atoms or an aryl group having 6 to 20 carbon atoms.

13. The complex compound according to claim 3 or 4, wherein B is each independently at least one selected from the group consisting of —N(R⁵)—, —O—, —C(R⁵)(R⁶)—, —Si(R⁵)(R⁶)—, —S—, —SO—, —SO₂— and —Se—,
wherein R⁵ and R⁶ each independently represent a hydrogen atom, an alkyl group having 1 to 20 carbon atoms or an aryl group having 6 to 20 carbon atoms.

14. The complex compound according to claim 1, wherein m is 0.

15. The complex compound according to claim 3 or 4, wherein n is 0.

16. The complex compound according to claim 1, wherein a+b=2.

17. The complex compound according to claim 4, wherein B is —S—, and n is 1.

18. The complex compound according to claim 10, wherein R¹, R², R³ and R⁴ are each independently a carboxylic acid group or a salt thereof, and m is 0.

19. The complex compound according to claim 10, wherein R' and R² are each independently a carboxylic acid group or a salt thereof, and m is 0.

20. The complex compound according to claim 1, wherein the metal atom is Fe, Ru or Os.

21. A photosensitizing coloring matter containing the complex compound defined in claim 1.

22. A photoelectric conversion device comprising an electroconductive substrate and a semiconductor fine particle layer having the photosensitizing coloring matter defined in claim 21 adsorbed thereon.

23. A photoelectrochemical battery comprising a photoelectric conversion device defined in claim 22, a charge moving layer and a counter electrode.
